(19) United States
(12) Patent Application Publication
(10) Pub. No.: US 2026/0343813 A1
(43) Pub. Date: Oct. 29, 2026

(54) REFRIGERANT CIRCULATION DEVICE

(71) Applicant: NIDEC CORPORATION, Kyoto (JP)

(72) Inventor: Toshihiko TOKESHI, Kyoto (JP)

(21) Appl. No.: 19/653,309

(22) Filed: Apr. 21, 2026

(30) Foreign Application Priority Data
Apr. 24, 2025 (JP) 2025-072367
Nov. 10, 2025 (JP) 2025-189237

(51) Int. Cl. H05K 7/20

(52) U.S. Cl. CPC H05K 7/20272

(57) ABSTRACT

A refrigerant circulation device includes a housing, a first lever, a second lever, a first holding portion, and a second holding portion. The housing accommodates a flow path and a pump connected to the flow path. The first lever is pivotable about a first axis along an in-plane direction of a first surface. The second lever is pivotable about a second axis along the in-plane direction of the first surface. The first holding portion is capable of holding a first end portion of the first lever. The second holding portion is capable of holding a second end portion of the second lever. A third end portion of the first lever is capable of abutting against a first abutment portion of a rack. A fourth end portion of the second lever is capable of abutting against a second abutment portion of the rack.

### CROSS-REFERENCE TO RELATED APPLICATIONS

The present invention claims priority under 35 U.S.C. § 119 to Japanese Patent Application Nos. 2025-072367 filed on Apr. 24, 2025, and 2025-189237 filed on Nov. 10, 2025, the entire contents of which are hereby incorporated herein by reference.

### 1. FIELD OF THE INVENTION

The present disclosure relates to refrigerant circulation devices.

### 2. BACKGROUND

Refrigerant circulation devices are known to cool a heat source such as a central processing unit (CPU) by transferring heat received from the heat source to a circulating refrigerant. As a known example, a configuration in which a refrigerant circulation device is placed in a rack is disclosed. However, the related art leaves room for improvement in terms of improving workability when inserting and removing the refrigerant circulation device into and from the rack.

### SUMMARY

A refrigerant circulation device according to an example embodiment of the present disclosure includes a housing, a first lever, a second lever, a first holding portion, and a second holding portion. The housing accommodates a flow path through which a refrigerant flows and a pump that is connected to the flow path to pump the refrigerant. The first lever is located on a first surface of the housing and is pivotable about a first axis along an in-plane direction of the first surface. The second lever is located on the first surface and is pivotable about a second axis along the in-plane direction of the first surface. The first holding portion is capable of holding a first end portion of the first lever, which is located farther from the first axis, of two end portions of the first lever in an extension direction thereof. The second holding portion is capable of holding a second end portion of the second lever, which is located farther from the second axis, of two end portions of the second lever in an extension direction thereof. A third end portion, which is another end portion located closer to the first axis, of two end portions of the first lever in the extension direction thereof can abut against a first abutment portion of a rack that houses the refrigerant circulation device. A fourth end portion, which is another end portion located closer to the second axis, of two end portions of the second lever in the extension direction thereof can abut against a second abutment portion of the rack. In a state where the first end portion is held by the first holding portion, the third end portion abuts against the first abutment portion. In a state where the second end portion is held by the second holding portion, the fourth end portion abuts against the second abutment portion.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a schematic perspective view illustrating a state in which a CDU according to an example embodiment of the present disclosure is stored in a rack.

FIG. 2 is a diagram illustrating a schematic configuration of a CDU according to an example embodiment.

FIG. 3 is a schematic perspective view of a first surface of a CDU according to an example embodiment.

FIG. 4 is a schematic perspective view of a second abutment portion of a rack according to an example embodiment and the vicinity thereof.

FIG. 5 is a diagram illustrating a state in which a fourth end portion of a second lever according to an example embodiment abuts against the second abutment portion of the rack.

FIG. 6 is a schematic cross-sectional view illustrating a configuration of a first lever, the second lever, a first holding portion, and a second holding portion according to an example embodiment of the present invention.

FIG. 7 is a schematic perspective cross-sectional view illustrating a connection portion connecting a third lever and the first holding portion according to an example embodiment of the present invention.

FIG. 8 is a schematic perspective cross-sectional view illustrating a configuration of the first lever, the second lever, the first holding portion, and the second holding portion according to an example embodiment of the present invention.

FIG. 9 is a schematic perspective cross-sectional view illustrating a configuration of the first holding portion and the second holding portion.

FIG. 10 is a schematic perspective view of a second surface of a CDU according to an example embodiment of the present invention.

FIG. 11 is a schematic cross-sectional view illustrating a configuration of a coupling according to an example embodiment of the present invention.

FIG. 12 is a schematic cross-sectional view illustrating a configuration of a coupling according to an example embodiment of the present invention.

FIG. 13 is a schematic cross-sectional view illustrating a configuration of the coupling according to the example embodiment.

FIG. 14 is a schematic cross-sectional view illustrating a configuration of a coupling according to an example embodiment of the present invention.

FIG. 15 is a schematic perspective view of a first surface of a CDU according to a modified example of an example embodiment of the present invention.

FIG. 16 is a schematic enlarged perspective view of a water cooling unit according to an example embodiment of the present invention.

FIG. 17 is a schematic perspective view illustrating a configuration of the CDU and a rotation mechanism according to an example embodiment of the present invention.

FIG. 18 is a schematic cross-sectional view illustrating a configuration of a rotation mechanism according to an example embodiment of the present invention.

FIG. 19 is a schematic enlarged side view illustrating a configuration of a groove portion and a protruding portion according to an example embodiment of the present invention.

### DETAILED DESCRIPTION

Below, configurations for implementing a refrigerant circulation device according to the present disclosure (hereinafter, referred to as “example embodiments”) will be described in detail with reference to the drawings. Note that the present disclosure is not limited to the example embodiments. The example embodiments can be appropriately combined as long as the processing content is not contradicted. In the following example embodiments, the same components are denoted by the same reference numerals, and redundant description will be omitted.

In addition, in the drawings referred to below, for ease of understanding, a Cartesian coordinate system may be shown in which an X-axis direction, a Y-axis direction, and a Z-axis direction are defined as being perpendicular to one another, and a positive Z-axis direction is a vertically upward direction.

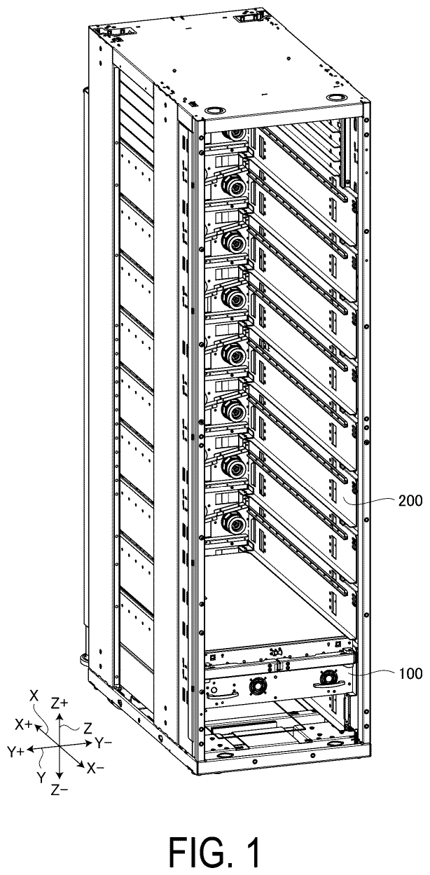

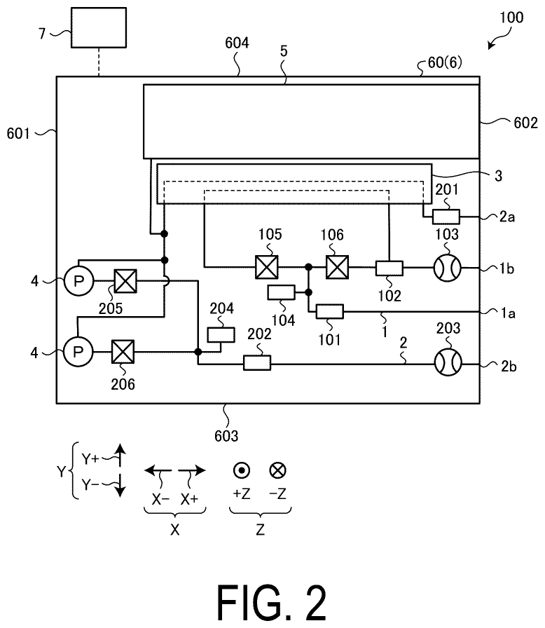

First, a configuration of a CDU 100 according to an example embodiment will be described with reference to FIGS. 1 and 2. FIG. 1 is a schematic perspective view illustrating a state in which the CDU 100 according to the present example embodiment is stored in a rack 200. FIG. 2 is a diagram illustrating a schematic configuration of the CDU 100 according to the present example embodiment. Note that “CDU” is an abbreviation for “Coolant Distribution Unit”. The CDU 100 is an example of a refrigerant circulation device.

The CDU 100 controls flow rate, temperature, quality, or distribution destination of the refrigerant supplied from the facility side. The CDU 100 sucks a primary refrigerant into the CDU 100 and pumps the primary refrigerant to the outside of the CDU 100. The CDU 100 sucks a secondary refrigerant into the CDU 100 and pumps the secondary refrigerant to the outside of the CDU 100.

The CDU 100 exchanges heat between the primary refrigerant and the secondary refrigerant. For example, refrigerants such as an antifreeze solution and pure water can be used as the primary refrigerant and the secondary refrigerant. Antifreeze solutions that can be used as refrigerants include an ethylene glycol aqueous solution and a propylene glycol aqueous solution. The primary refrigerant and the secondary refrigerant may be the same or different types. At least one of the primary refrigerant and the secondary refrigerant may be a gas refrigerant.

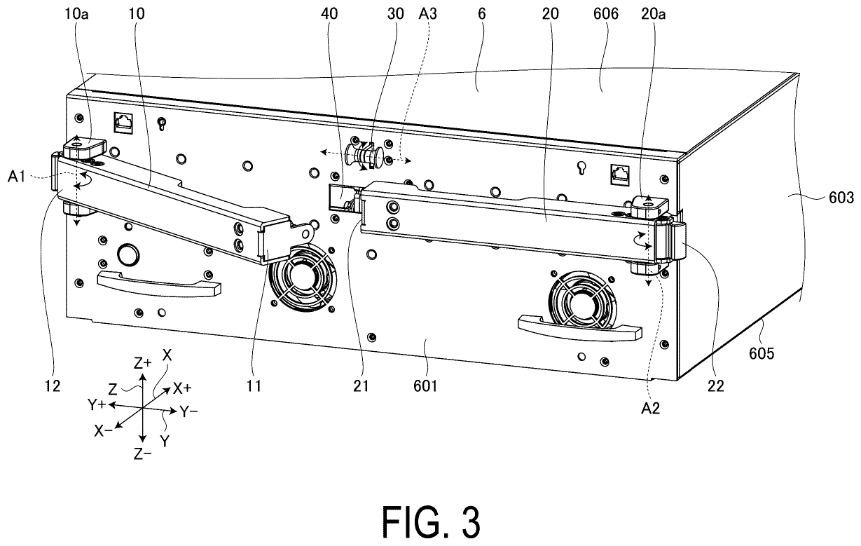

The CDU 100 is stored inside the rack 200. As illustrated in FIG. 1, the CDU 100 may be stored in a lower layer of the rack 200. A first surface 601 of the CDU 100 (see FIG. 3) may be exposed outside the rack 200, or may be exposed outside by opening a door (not illustrated) of the rack 200.

The CDU 100 includes a primary flow path 1, a secondary flow path 2, a heat exchanger 3, a pump 4, a tank 5, a housing 6, and a control unit 7. The primary refrigerant flows through the primary flow path 1. The secondary refrigerant flows through the secondary flow path 2. The primary flow path 1 and the secondary flow path 2 are examples of a flow path.

The heat exchanger 3 is connected to the primary flow path 1 and the secondary flow path 2. The primary refrigerant and the secondary refrigerant flow into and flow out from the heat exchanger 3. The heat exchanger 3 exchanges heat between the primary refrigerant and the secondary refrigerant therein. The heat exchange type of the heat exchanger 3 is, for example, a plate type.

The pump 4 is connected to the secondary flow path 2. The pump 4 has an internal flow path. When the pump 4 is driven, the secondary refrigerant is sucked into the internal flow path of the pump 4, and then pumped out from the internal flow path of the pump 4. This causes the secondary refrigerant to circulate between the CDU 100 and an external cold plate. The number of the pumps 4 installed is not limited. For example, the number of the pumps 4 installed is two. That is, the CDU 100 may include multiple pumps 4.

The tank 5 stores a refrigerant used as the secondary refrigerant. The tank 5 is connected to the secondary flow path 2. The tank 5 can supply the refrigerant to the secondary flow path 2.

The housing 6 has an accommodation space 60. The housing 6 accommodates the primary flow path 1, the secondary flow path 2, the heat exchanger 3, the pump 4, and the tank 5 in the accommodation space 60.

The control unit 7 is connected to sensors such as a temperature and humidity sensor located in the CDU 100, temperature sensors 101 and 102, a flow rate sensor 103, and a primary refrigerant pressure sensor 104 located in the primary flow path 1, temperature sensors 201 and 202, a flow rate sensor 203, and a secondary refrigerant pressure sensor 204 located in the secondary flow path 2. The control unit 7 controls the pump 4, valves 105 and 106 located in the primary flow path 1, and valves 205 and 206 located in the secondary flow path 2.

Note that FIG. 2 illustrates an example of the configuration of the CDU 100, and the CDU 100 may further include components other than the components illustrated in FIG. 3. For example, the CDU 100 may further include a display operation unit (not illustrated). The display operation unit displays operation status of the CDU 100, measurement values of the sensors, and the like. The display operation unit is, for example, a touch panel display. The CDU 100 may further include a display unit (not illustrated) that does not have an operation surface. The display unit is, for example, a display such as a liquid crystal display or an organic EL display.

Next, the housing 6 of the CDU 100 according to the present example embodiment will be described with reference to FIGS. 2 and 3. FIG. 3 is a schematic perspective view of the first surface 601 of the CDU 100 according to the present example embodiment.

In a plan view from the Z-axis direction, the accommodation space 60 of the housing 6 is substantially rectangular, with the X-axis direction as a longitudinal direction and the Y-axis direction as a transverse direction. That is, the accommodation space 60 extends in the X-axis direction and the Y-axis direction, which intersect each other, and is longer in the X-axis direction than in the Y-axis direction. The accommodation space 60 has the Z-axis direction as a depth direction. A width (depth) of the accommodation space 60 in the Z-axis direction is smaller than widths of the accommodation space 60 in the X-axis direction and the Y-axis direction.

The housing 6 has the first surface 601 to a sixth surface 606. The first surface 601 to the sixth surface 606 surround the accommodation space 60. That is, the housing 6 has a space surrounded by the first surface 601 to the sixth surface 606 as the accommodation space 60.

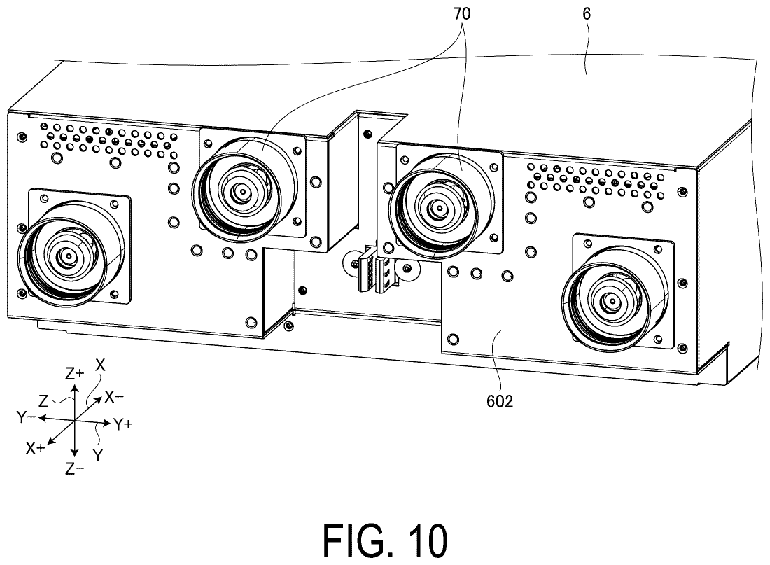

The first surface 601 and the second surface 602 are located facing each other in the X-axis direction with the accommodation space 60 interposed therebetween. The first surface 601 is located on one side in the X-axis direction (a negative side in the X-axis direction). As illustrated in FIG. 3, a first lever 10 and a second lever 20 are located on the first surface 601. Configurations of the first lever 10 and the second lever 20 will be described below. The second surface 602 is located on another side in the X-axis direction (a positive side in the X-axis direction). The second surface 602 is located opposite the first surface 601. As illustrated in FIG. 2, the second surface 602 is provided with an inlet 1a and an outlet 1b for the primary refrigerant, and an inlet 2a and an outlet 2b for the secondary refrigerant. Couplings 70 (see FIG. 10) are connected to the inlets 1a and 2a and the outlets 1b and 2b, respectively. A configuration of the coupling 70 will be described below.

The third surface 603 and the fourth surface 604 are located to face each other in the Y-axis direction with the accommodation space 60 interposed therebetween. The third surface 603 is located on one side in the Y-axis direction (a negative side in the Y-axis direction). A guide rail (not illustrated) extending in the X-axis direction may be located on the third surface 603. This guide rail may engage with a guide rail (not illustrated) located on a surface of the rack 200 facing the third surface 603. The fourth surface 604 is located on another side in the Y-axis direction (a positive side in the Y-axis direction). A guide rail (not illustrated) extending in the X-axis direction is located on the fourth surface 604. This guide rail may engage with a guide rail (not illustrated) located on a surface of the rack 200 facing the fourth surface 604.

The fifth surface 605 and the sixth surface 606 are located to face each other in the Z-axis direction with the accommodation space 60 interposed therebetween. The fifth surface 605 is located on one side in the Z-axis direction (a negative side in the Z-axis direction). The sixth surface 606 is located on another side in the Z-axis direction (a positive side in the Z-axis direction). In the following description, the sixth surface 606 may be referred to as a top surface 606.

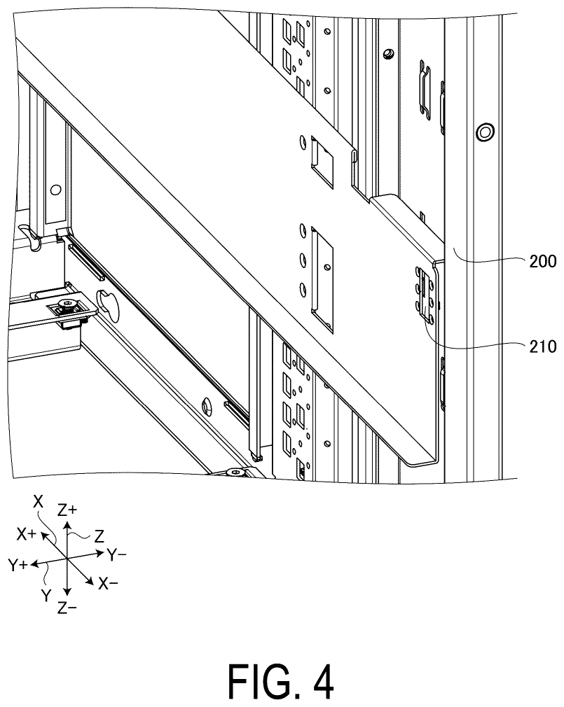

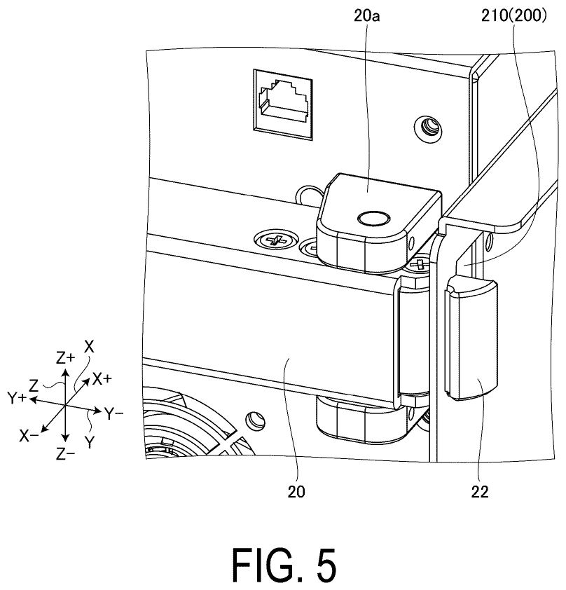

Next, the configurations of the first lever 10 and the second lever 20 according to the example embodiment will be described with reference to FIGS. 3 to 5. FIG. 4 is a schematic perspective view of a second abutment portion 210 of the rack 200 according to the present example embodiment and the vicinity thereof. FIG. 5 is a diagram illustrating a state in which a fourth end portion 22 of the second lever 20 according to the present example embodiment abuts against the second abutment portion 210 of the rack 200.

The first lever 10 is located on the first surface 601 of the housing 6. The first lever 10 is supported by a support part 10a so as to be pivotable about a first axis A1 along an in-plane direction of the first surface 601. The first lever 10 includes a first end portion 11 and a third end portion 12.

The first end portion 11 is an end portion located farther from the first axis A1 of both end portions of the first lever 10 in an extension direction thereof. The first end portion 11 can be held by a first holding portion 40 located on the first surface 601. A specific holding configuration of the first holding portion 40 will be described below.

The third end portion 12 is another end portion located closer to the first axis A1 of both end portions of the first lever 10 in the extension direction thereof. The third end portion 12 is capable of abutting against a first abutment portion (not illustrated) of the rack 200. For example, the first abutment portion may be a through-hole. In this case, the third end portion 12 can be inserted into the through-hole.

The second lever 20 is located on the first surface 601 of the housing 6. The second lever 20 is supported by a support part 20a so as to be pivotable about a second axis A2 along the in-plane direction of the first surface 601. The second lever 20 includes a second end portion 21 and the fourth end portion 22.

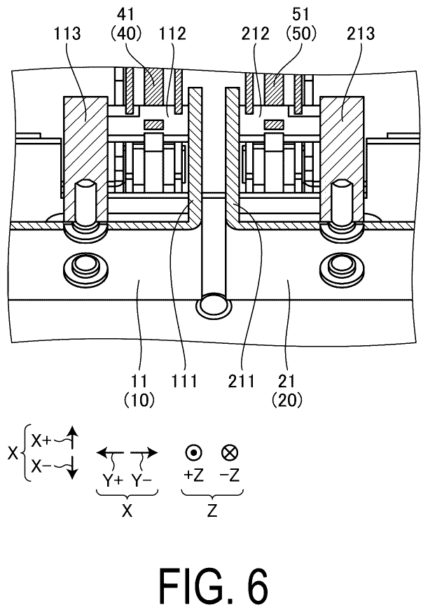

The second end portion 21 is an end portion located farther from the second axis A2 of both end portions of the first lever 10 in an extension direction thereof. The second end portion 21 can be held by a second holding portion 50 (see FIG. 6) located on the first surface 601.

The fourth end portion 22 is another end portion located closer to the second axis A2 of both end portions of the first lever 10 in the extension direction thereof. The fourth end portion 22 is capable of abutting against the second abutment portion 210 of the rack 200. For example, as illustrated in FIGS. 4 and 5, the second abutment portion 210 may be a through-hole. In this case, the fourth end portion 22 can be inserted into the second abutment portion 210 as a through-hole.

Here, with the first end portion 11 of the first lever 10 held by the first holding portion 40, the third end portion 12 of the first lever 10 abuts against the first abutment portion of the rack 200. Similarly, with the second end portion 21 of the second lever 20 held by the second holding portion 50, the fourth end portion 22 of the second lever 20 abuts against the second abutment portion 210 of the rack 200 (see the second lever 20 in FIGS. 3 and 5).

From this state, when a user pulls the first end portion 11 of the first lever 10 toward the user, that is, when the user pulls the first end portion 11 of the first lever 10 in a direction away from the housing 6 (see the first lever 10 in FIG. 3), the first lever 10 pivots about the first axis A1, and the third end portion 12 moves away from the first abutment portion. Similarly, when the user pulls the second end portion 21 of the second lever 20 toward the user, the second lever 20 pivots about the second axis A2, and the fourth end portion 22 moves away from the second abutment portion 210. This allows the CDU 100 to be removed from the rack 200.

On the other hand, when storing the CDU 100 in the rack 200, the user pushes the first end portion 11 of the first lever 10, that is, the user pushes the first end portion 11 of the first lever 10 in a direction toward the housing 6, causing the first lever 10 to pivot about the first axis A1 and the third end portion 12 to abut against the first abutment portion. Similarly, when the user pushes the second end portion 21 of the second lever 20, the second lever 20 pivots about the second axis A2, and the fourth end portion 22 abuts against the second abutment portion 210. Thereafter, the first end portion 11 is held by the first holding portion 40 and the second end portion 21 is held by the second holding portion 50, thus the CDU 100 may be fixed to the rack 200.

In this way, in the CDU 100 according to the present disclosure, the third end portion 12 of the first lever 10 abuts against the first abutment portion of the rack 200, and the first end portion 11 is held by the first holding portion 40. Similarly, the fourth end portion 22 of the second lever 20 abuts against the second abutment portion 210 of the rack 200, and the second end portion 21 is held by the second holding portion 50. With this configuration, by appropriately moving the first lever 10 and the second lever 20, the CDU 100 can be easily fixed to the rack 200 or the CDU 100 can be easily removed from the rack 200. Further, since the fixing and the removal can be completed by simply pivoting the first lever 10 and the second lever 20, the CDU 100 can be easily inserted into and removed from the rack 200.

As illustrated in FIG. 3, the first lever 10 and the second lever 20 may be positioned so as to overlap in a direction(Z-axis direction) perpendicular to the extension directions of the first lever 10 and the second lever 20.

This makes it easier for the user to recognize positions of the first lever 10 and the second lever 20, improving operability of the first lever 10 and the second lever 20.

As illustrated in FIG. 5, the fourth end portion 22 of the second lever 20 may include a hook-shaped portion. With this configuration, the fourth end portion 22 passes through the second abutment portion 210, which serves as a through-hole, and the hook-shaped portion is positioned so as to sandwich a front surface and a back surface of the rack 200 around the second abutment portion 210, thereby restricting movement in a direction (the Y-axis direction in FIG. 3) along the extension direction of the second lever 20. Note that the third end portion 12 of the first lever 10 may also include a hook-shaped portion.

Next, states of the first holding portion 40 and the second holding portion 50 according to the example embodiment and a configuration of a third lever 30 according to the example embodiment will be described with reference to FIG. 3.

The first holding portion 40 may be switchable between a restricting state in which the first holding portion 40 holds the first end portion 11 to restrict movement of the first lever 10, and a releasing state in which the first holding portion 40 releases the restricting state. Similarly, the second holding portion 50 may be switchable between a restricting state in which the second holding portion 50 holds the second end portion 21 to restrict movement of the second lever 20, and a releasing state in which the second holding portion 50 releases the restricting state.

This reduces a possibility that the first lever 10 and the second lever 20 are pivoted by an erroneous operation in the restricting state.

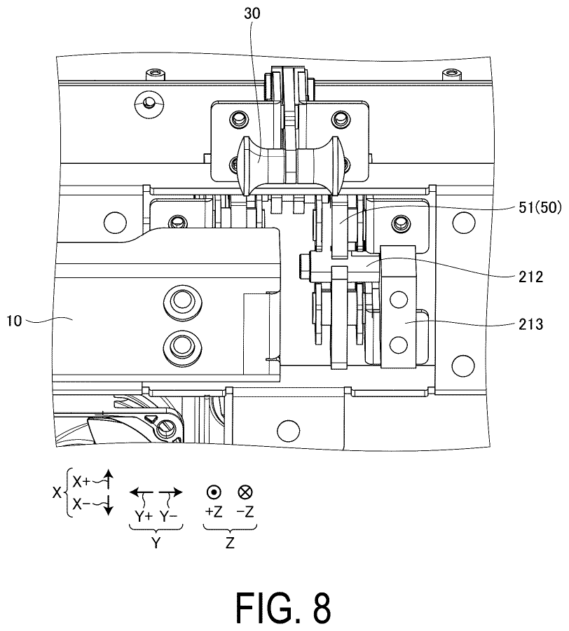

As illustrated in FIG. 3, the CDU 100 may further include the third lever 30. The third lever 30 is located on the first surface 601 of the housing 6. To be specific, the third lever 30 may be located closer to the top surface 606 of the housing 6 than the first holding portion 40 and the second holding portion 50 on the first surface 601. The third lever 30 may at least partially overlap the first holding portion 40 and the second holding portion 50 in a vertical direction (Z-axis direction) (see FIG. 8).

The third lever 30 may be rotatable about a third axis A3 that follows the in-plane direction of the first surface 601 and intersects the first axis A1 and the second axis A2 that are parallel to each other.

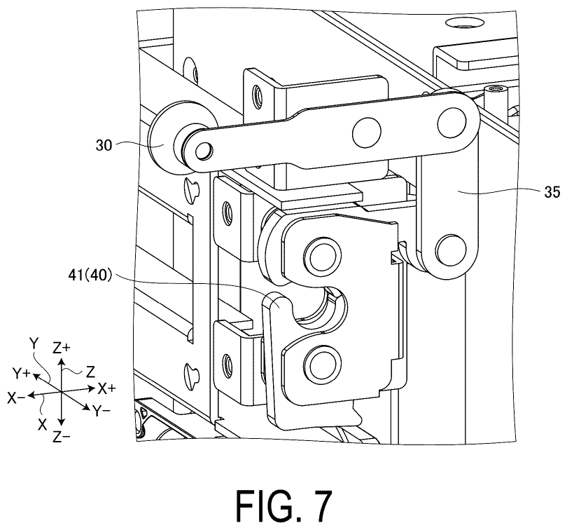

The third lever 30 may switch the states of the first holding portion 40 and the second holding portion 50 from the restricting state to the releasing state. To be specific, the third lever 30 may be connected to the first holding portion 40 and the second holding portion 50 via connection portions 35 (see FIG. 7), and may simultaneously switch the states of the first holding portion 40 and the second holding portion 50.

This allows the first lever 10 and the second lever 20 to be switched from the restricting state to the releasing state by operating only the third lever 30, improving operability.

As described above, the third lever 30 is located closer to the top surface 606 of the housing 6 than the first holding portion 40 and the second holding portion 50 on the first surface 601, which makes it possible for the user to easily operate the third lever 30 from an upper portion of the CDU 100, thereby improving operability of the third lever 30. By vertically overlapping the third lever 30 with the first holding portion 40 and the second holding portion 50, it is easy to visually confirm changes in the states of the first holding portion 40 and the second holding portion 50 caused by operating the third lever 30. By connecting the third lever 30 with the first holding portion 40 and the second holding portion 50 in an overlapping manner in the vertical direction, it is possible to simplify interlocking mechanisms between the third lever 30 and the first holding portion 40 and the second holding portion 50.

Since the third lever 30 is rotatable about the third axis A3, it is easy for the user to secure an operation space, and the operability of the third lever 30 can be improved.

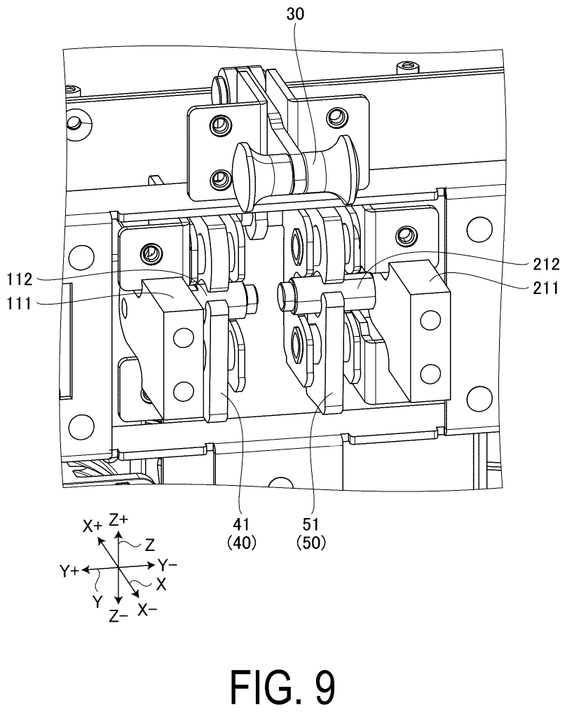

Next, configurations of the first lever 10, the second lever 20, the first holding portion 40, and the second holding portion 50 according to the present example embodiment will be described with reference to FIGS. 3 and 6 to 9. FIGS. 6 and 8 are schematic perspective cross-sectional views, respectively, illustrating the configurations of the first lever 10, the second lever 20, the first holding portion 40, and the present second holding portion 50 according to the example embodiment. FIG. 7 is a schematic perspective cross-sectional view illustrating the connection portion 35 connecting the third lever 30 and the first holding portion 40 according to the present example embodiment. FIG. 9 is a schematic perspective cross-sectional view illustrating the configuration of the first holding portion 40 and the second holding portion 50.

As illustrated in FIG. 6, the first lever 10 may include a first protruding portion 111 and a first tubular portion 112. The first protruding portion 111 protrudes from the first end portion 11. The first protruding portion 111 extends in a first direction that intersects the extension direction of the first lever 10 and the first axis A1. The first tubular portion 112 is connected to the first protruding portion 111 and extends in a direction parallel to the extension direction of the first lever 10. The first tubular portion 112 is formed in a cylindrical shape, and an outer periphery thereof can be held by the first holding portion 40.

Similarly, the second lever 20 may include a second protruding portion 211 and a second tubular portion 212. The second protruding portion 211 protrudes from the second end portion 21. The second protruding portion 211 extends in a second direction that intersects the extension direction of the second lever 20 and the second axis A2. The second tubular portion 212 is connected to the second protruding portion 211 and extends in a direction parallel to the extension direction of the second lever 20. The second tubular portion 212 is formed in a cylindrical shape, and an outer periphery thereof can be held by the second holding portion 50.

The first holding portion 40 includes a first hook portion 41 that hooks the first tubular portion 112, and a first spring (not illustrated) that biases the first hook portion 41. The first hook portion 41 is biased by the first spring in a direction in which the first hook portion 41 clamps the outer periphery of the first tubular portion 112.

Similarly, the second holding portion 50 includes a second hook portion 51 that hooks the second tubular portion 212 and a second spring (not illustrated) that biases the second hook portion 51. The second hook portion 51 is biased by the second spring in a direction in which the second hook portion 51 clamps the outer periphery of the second tubular portion 212.

When the first end portion 11 of the first lever 10 is pushed into the first surface 601 of the housing 6, the first tubular portion 112 is inserted into the first holding portion 40 and fixed so that the outer periphery of the first tubular portion 112 is clamped by the first hook portion 41. This achieves the restricting state in which the movement of the first lever 10 is restricted. Similarly, when the second end portion 21 of the second lever 20 is pushed into the first surface 601 of the housing 6, the second tubular portion 212 is inserted into the second holding portion 50 and fixed so that the outer periphery of the second tubular portion 212 is clamped by the second hook portion 51. This achieves the restricting state in which the movement of the second lever 20 is restricted.

As illustrated in FIG. 7, the third lever 30 is connected to the first holding portion 40 and the second holding portion 50 via the connection portions 35, and is pivoted about the third axis A3 to move the first hook portion 41 and the second hook portion 51 toward release positions. To be specific, by pulling down the third lever 30, the first hook portion 41 moves in a direction of releasing the first tubular portion 112, and the second hook portion 51 moves in a direction of releasing the second tubular portion 212. Thus, the first tubular portion 112 and the second tubular portion 212 are released from the first hook portion 41 and the second hook portion 51, respectively, and the first lever 10 and the second lever 20 are released from restriction and enter a releasing state.

As described above, the first holding portion 40 includes the first hook portion 41 and the second holding portion 50 includes the second hook portion 51, so that the first lever 10 and the second lever 20 can be reliably placed in a restricting state with a simple configuration, and the restricting state can be released all at once by operating the third lever 30. Thus, the CDU 100 has excellent workability and operability. Note that, here, an example in which the restricting state can be switched to the releasing state by pulling down the third lever 30 is shown, but the configuration is not limited thereto, and the restricting state can be switched to the releasing state by pulling up the third lever 30.

As illustrated in FIG. 6, the first lever 10 may further include a third protruding portion 113. The third protruding portion 113 extends from the first end portion 11 in the first direction (in a positive X-axis direction in FIG. 6). The first tubular portion 112 may be connected to the first protruding portion 111 at one end portion and connected to the third protruding portion 113 at another end portion. By supporting both ends of the first tubular portion 112 in this manner, connection strength between the first tubular portion 112 and the first protruding portion 111, and connection strength between the first tubular portion 112 and the third protruding portion 113, can be improved.

Similarly, the second lever 20 may further include a fourth protruding portion 213. The fourth protruding portion 213 extends from the second end portion 21 in the first direction (in the positive X-axis direction in FIG. 6). The second tubular portion 212 may be connected to the second protruding portion 211 at one end portion and connected to the fourth protruding portion 213 at another end portion. By supporting both ends of the second tubular portion 212 in this manner, connection strength between the second tubular portion 212 and the second protruding portion 211, and connection strength between the second tubular portion 212 and the fourth protruding portion 213, can be improved.

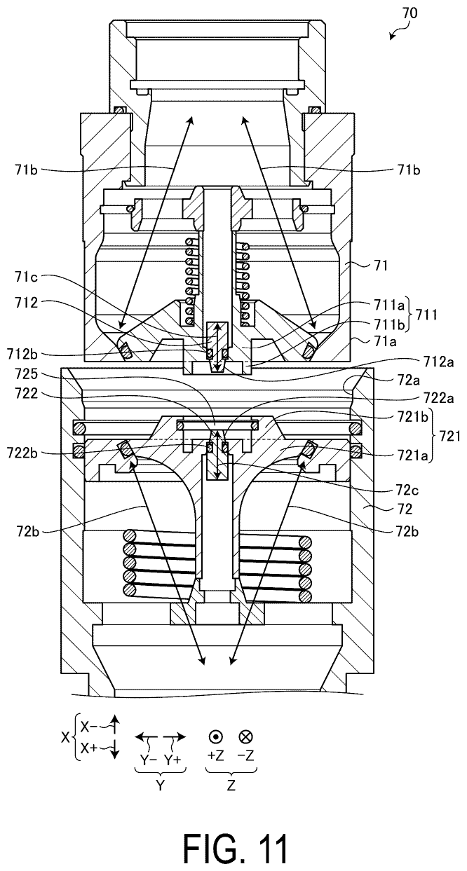

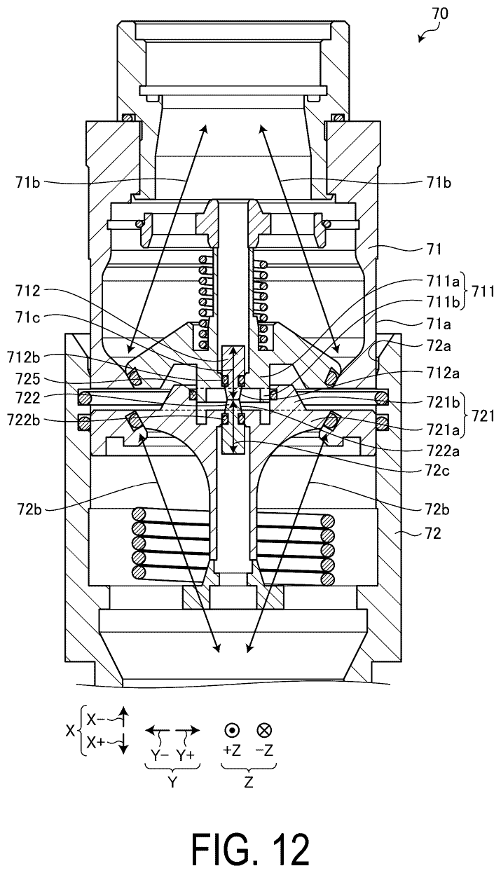

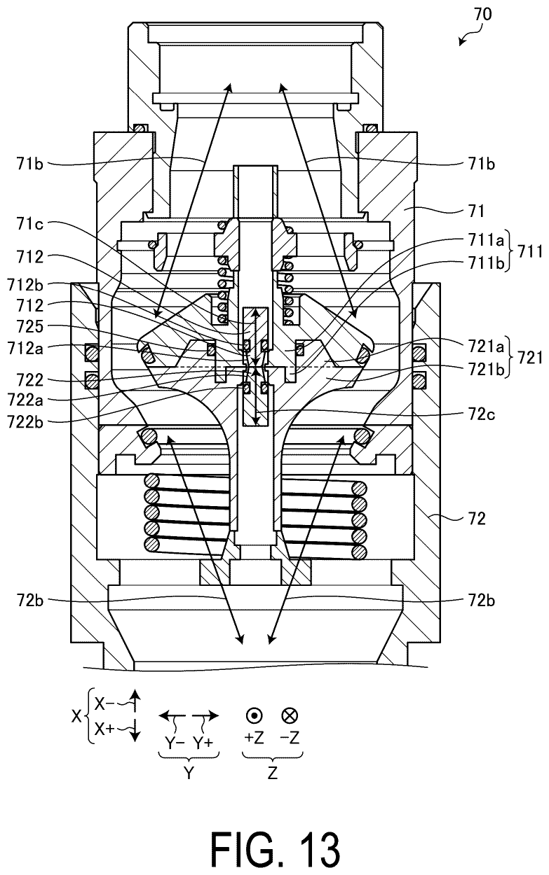

Next, the configuration of the coupling 70 according to the present example embodiment will be described with reference to FIGS. 10 to 14. FIG. 10 is a schematic perspective view of the second surface 602 of the CDU 100 according to the present example embodiment. FIGS. 11 to 14 are schematic cross-sectional views illustrating the configurations of the coupling 70 according to the present example embodiment. Note that FIG. 10 illustrates a state in which first portions 71 of the couplings 70 are provided on the second surface 602. FIG. 11 illustrates a state in which the first portion 71 and a second portion 72 of the coupling 70 are not fitted together. FIG. 12 illustrates a state in which part of a protruding portion 71a of the first portion 71 of the coupling 70 is inserted into a recessed portion 72a of the second portion 72. FIG. 13 illustrates a state in which the first portion 71 and the second portion 72 of the coupling 70 are fitted together. That is, FIGS. 11 to 13 illustrate changes in state when the first portion 71 and the second portion 72 are fitted together. In FIGS. 11 to 13, a boundary between a main valve body 711a and a protruding portion 711b is indicated by a dashed line.

The couplings 70 are located on the second surface 602 of the housing 6. To be specific, the second surface 602 is provided with the inlet 1a and the outlet 1b for the primary refrigerant, and the inlet 2a and the outlet 2b for the secondary refrigerant (see FIG. 2). The couplings 70 are connected to the inlets 1a and 2a and the outlets 1b and 2b, respectively.

The coupling 70 includes the first portion 71 and the second portion 72. The first portion 71 includes the protruding portion 71a that protrudes in a direction away from the second surface 62 (here, in the positive X-axis direction). The first portion 71 has a first main flow path 71b and a first auxiliary flow path 71c that communicate with the primary flow path 1 or the secondary flow path 2 (see FIG. 2), and includes a first main valve 711 and a first auxiliary valve 712. The first main valve 711 is provided in the first main flow path 71b. The first auxiliary valve 712 is provided in the first auxiliary flow path 71c.

The second portion 72 includes the recessed portion 72a that fits with the protruding portion 71a of the first portion 71. The second portion 72 has a second main flow path 72b that communicates with the first main flow path 71b and a second auxiliary flow path 72c that communicates with the first auxiliary flow path 71c, and includes a second main valve 721 and a second auxiliary valve 722. The second main valve 721 is provided in the second main flow path 72b. The second auxiliary valve 722 is provided in the second auxiliary flow path 72c.

A flow path area of the main flow path of the coupling 70 described above may be larger than a flow path area of the auxiliary flow path. To be specific, in the first portion 71, a flow path area of the first main flow path 71b may be larger than a flow path area of the first auxiliary flow path 71c. Similarly, in the second portion 72, a flow path area of the second main flow path 72b may be larger than a flow path area of the second auxiliary flow path 72c.

The CDU 100 provides excellent workability when inserting and removing the couplings 70, so that when inserting and removing the CDU 100 into and from the rack 200, the couplings 70 can be easily inserted into and removed from the housing 6. Therefore, the CDU 100 of the present disclosure can be easily inserted into and removed from the rack 200.

As illustrated in FIGS. 11 to 13, the first auxiliary valve 712 may protrude further than the first main valve 711 in a direction away from the second surface 602 (here, in the positive X-axis direction). To be specific, the first main valve 711 includes the main valve body 711a and the protruding portion 711b. The protruding portion 711b is connected to the main valve body 711a and protrudes in the direction away from the second surface 602 (here, in the positive X-axis direction) from a surface of the main valve body 711a facing the second main valve 721. As illustrated in FIG. 11, the first auxiliary valve 712 may protrude further than the main valve body 711a of the first main valve 711 in the direction away from the second surface 602 (here, in the positive X-axis direction).

In this way, the first auxiliary valve 712 protrudes further than the first main valve 711 in the direction away from the second surface 602 (here, in the positive X-axis direction), so that when the second portion 72 is fitted to the first portion 71, the first auxiliary valve 712 and the second auxiliary valve 722 are first connected, and the first auxiliary flow path 71c and the second auxiliary flow path 72c communicate with each other. Thereafter, the first main valve 711 and the second main valve 721 are connected, and the first main flow path 71b and the second main flow path 72b communicate with each other. That is, the refrigerant can flow through the auxiliary flow path before the main flow path, and the auxiliary flow path equalizes internal pressure, reducing force required to insert the second portion 72 compared to a configuration in which the auxiliary flow path is not provided.

Note that the second auxiliary valve 722 may protrude further toward the second surface 602 (here, in a negative X-axis direction) than the second main valve 721. To be specific, the second main valve 721 includes a main valve body 721a and a protruding portion 721b. The protruding portion 721b is connected to the main valve body 721a and protrudes toward the second surface 602 (here, in the negative X-axis direction) from a surface of the main valve body 721a facing the first main valve 711. As illustrated in FIG. 11, the second auxiliary valve 722 may protrude further than the main valve body 711a of the first main valve 711 in the direction away from the second surface 602 (here, in the positive X-axis direction).

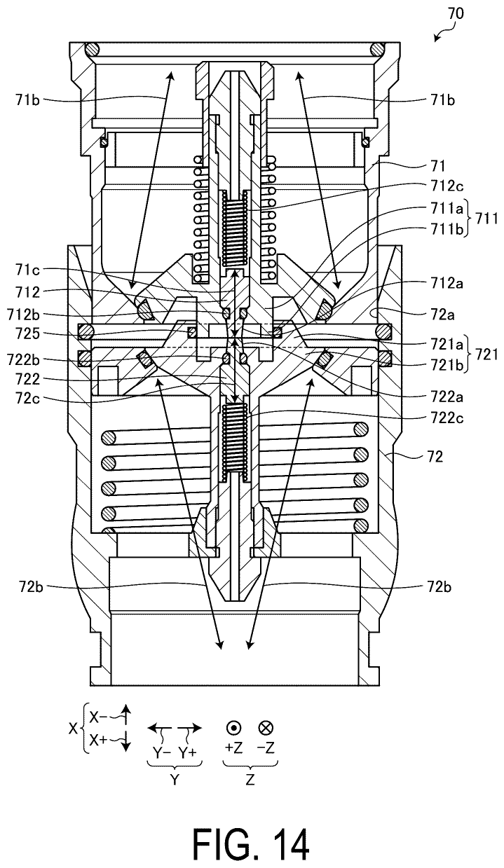

As illustrated in FIGS. 11 to 13, the first auxiliary valve 712 and the second auxiliary valve 722 may be movable in an axial direction (here, the X-axis direction). As illustrated in FIG. 14, the first portion 71 may include a spring 712c that biases the first auxiliary valve 712 in the axial direction from the rear (the negative side in the X-axis direction). Similarly, the second portion 72 may include a spring 722c that biases the second auxiliary valve 722 in the axial direction from the rear (the positive side in the X-axis direction). This allows the first auxiliary valve 712 and the second auxiliary valve 722 to move in the axial direction.

As illustrated in FIG. 11, the first auxiliary valve 712 may have an inclined surface 712a that is inclined relative to the axial direction. An O-ring 712b may be provided on the inclined surface 712a. Similarly, the second auxiliary valve 722 may have an inclined surface 722a that is inclined relative to the axial direction. An O-ring 722b may be provided on the inclined surface 722a.

As illustrated in FIG. 11, the protruding portion 711b may be located around the first auxiliary valve 712. Similarly, the protruding portion 721b may be located around the second auxiliary valve 722. The protruding portions 711b and 721b facilitate formation of the auxiliary flow path.

As illustrated in FIG. 11, the second portion 72 may further include a seal 725 provided along an outer circumferential surface of a space in which the second auxiliary valve 722 is provided. To be specific, the protruding portion 721b located around the second auxiliary valve 722 has a groove portion on a surface facing the second auxiliary valve 722. The seal 725 may be located in this groove portion. In this way, by providing the second portion 72 with the seal 725, it is possible to reduce leakage of the refrigerant to the outside of the coupling 70 when the refrigerant flows through the auxiliary flow path. The seal 725 is, for example, an O-ring.

Note that although an example in which the coupling 70 includes the first portion 71 and the second portion 72 is described here, the coupling 70 may include only the first portion 71.

As described above, in the CDU 100 according to the example embodiment, the third end portion 12 of the first lever 10 abuts against the first abutment portion of the rack 200, and the first end portion 11 is held by the first holding portion 40. Similarly, the fourth end portion 22 of the second lever 20 abuts against the second abutment portion 210 of the rack 200, and the second end portion 21 is held by the second holding portion 50. With this configuration, by appropriately moving the first lever 10 and the second lever 20, the CDU 100 can be easily fixed to the rack 200 or the CDU 100 can be easily removed from the rack 200. Further, since the fixing and the removal can be completed by simply pivoting the first lever 10 and the second lever 20, the CDU 100 can be easily inserted into and removed from the rack 200.

Note that although an example in which the third end portion 12 of the first lever 10 is inserted into the through-hole provided in the rack 200 is described here, the configuration in which the third end portion 12 abuts against the first abutment portion is not limited thereto. For example, the first abutment portion may be a recessed portion. In this case, the third end portion 12 may be able to fit into this recessed portion. Alternatively, the first abutment portion may be a member having a stepped shape. In this case, the third end portion 12 may be able to engage with this stepped portion. Similarly, in the second lever 20, the configuration in which the fourth end portion 22 abuts against the second abutment portion 210 is not limited to the example illustrated in FIG. 5.

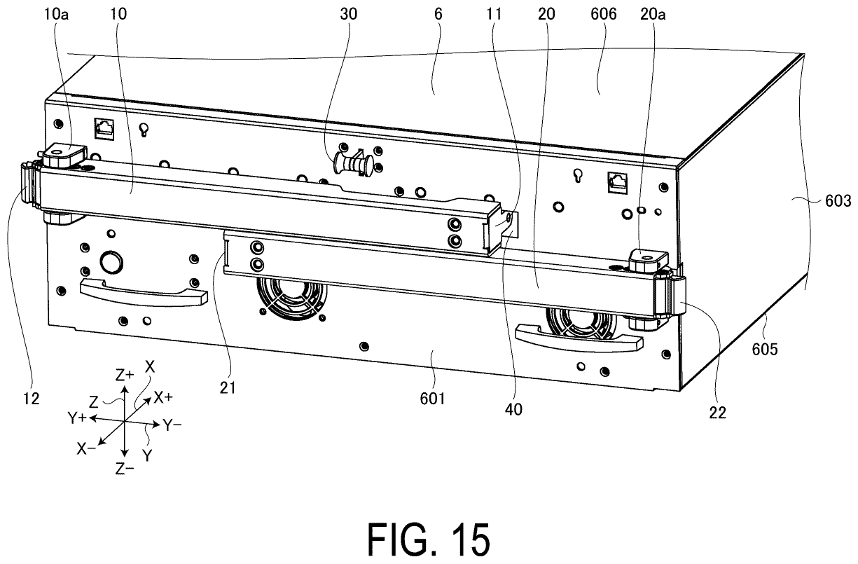

FIG. 15 is a schematic perspective view of a first surface 601 of a CDU 100 according to a modified example of an example embodiment of the present invention.

As illustrated in FIG. 15, a first lever 10 and a second lever 20 may be located at different positions in a direction perpendicular to extension directions of the first lever 10 and the second lever 20 (Z-axis direction). To be specific, the first lever 10 may be located on another side in the Z-axis direction (a positive side in the Z-axis direction) with respect to the second lever 20.

This allows respective lengths of the first lever 10 and the second lever 20 to be increased, as illustrated in FIG. 15. Therefore, by utilizing leverage, the CDU 100 can be inserted and removed with less force.

In this case as well, a third end portion 12 of the first lever 10 abuts against a first abutment portion of a rack 200, and a first end portion 11 is held by a first holding portion 40. Similarly, a fourth end portion 22 of the second lever 20 abuts against a second abutment portion 210 of the rack 200, and a second end portion 21 is held by a second holding portion 50. Therefore, by appropriately moving the first lever 10 and the second lever 20, the CDU 100 can be easily inserted into and removed from the rack 200.

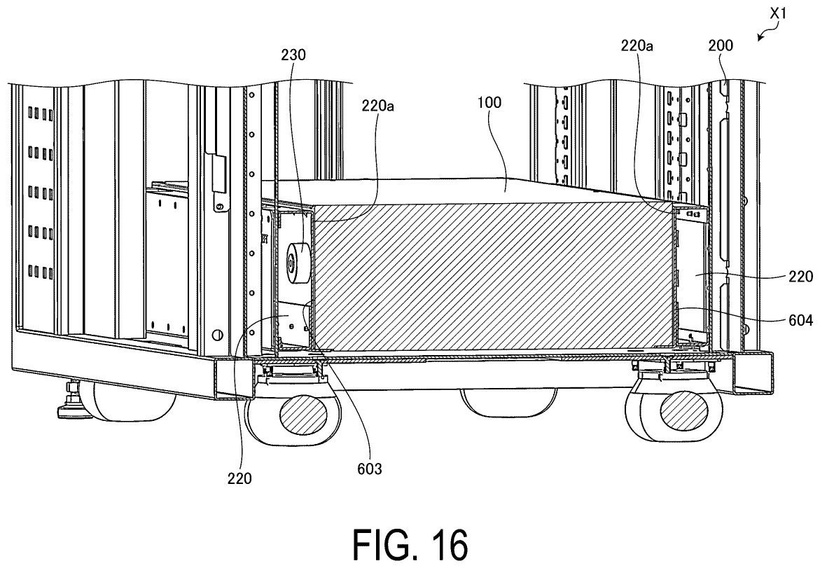

FIG. 16 is a schematic enlarged perspective view of a water cooling unit X1 according to the present example embodiment. As illustrated in FIG. 16, the water cooling unit X1 includes the CDU 100 and the rack 200 described above, and a rotation mechanism 230.

The rack 200 stores the CDU 100. The rack 200 may include spacers 220 located facing the third surface 603 and the fourth surface 604 of the CDU 100, respectively. The third surface 603 and the fourth surface 604 of the CDU 100 are examples of first side surfaces that face the spacers 220. The spacer 220 may be a box-shaped member. The spacer 220 has a side surface 220a that faces the third surface 603 or the fourth surface 604. The side surface 220a of the spacer 220 is an example of a second side surface that faces the CDU 100.

The rotation mechanisms 230 are located within the spacers 220. To be specific, one of the two rotation mechanisms 230 is located within the spacer 220 that faces the third surface 603, and the other is located within the spacer 220 that faces the fourth surface 604. The rotation mechanism 230 is attached to the side surface 220a of the spacer 220, that is, a sidewall of the spacer 220 on an inner side in the example of FIG. 16. One of the two rotation mechanisms 230 is in contact with the third surface 603 of the CDU 100 and rotates in accordance with relative movement of the third surface 603 relative to the side surface 220a. The other of the two rotation mechanisms 230 is in contact with the fourth surface 604 of the CDU 100 and rotates in accordance with relative movement of the fourth surface 604 relative to the side surface 220a.

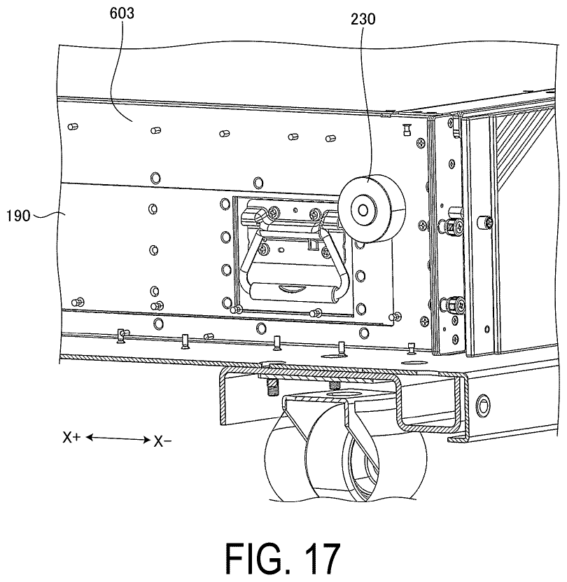

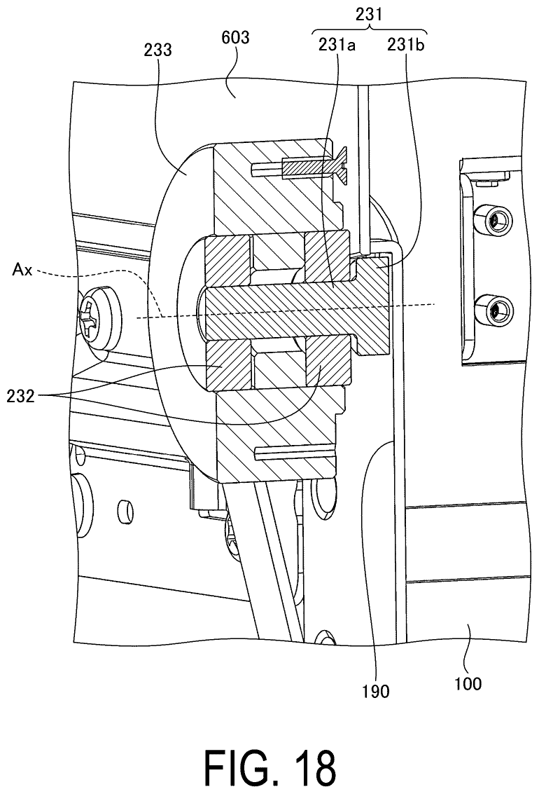

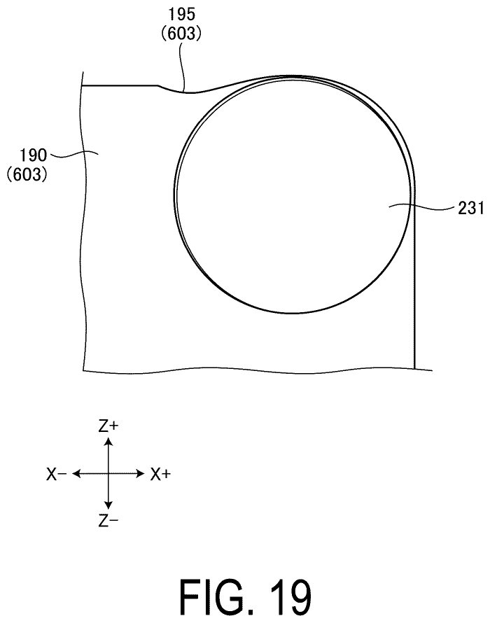

Next, an example of a configuration and movement of the rotation mechanism 230 according to the embodiment will be described with reference to FIGS. 17 to 19. FIG. 17 is a schematic perspective view illustrating a configuration of the CDU 100 and the rotation mechanism 230 according to the present example embodiment. FIG. 18 is a schematic cross-sectional view illustrating a configuration of the rotation mechanism 230 according to the present example embodiment. FIG. 19 is a schematic enlarged side view illustrating a configuration of a groove portion 190 and a protruding portion 195 according to the present example embodiment.

Note that for ease of understanding, the spacer 220 is omitted in FIGS. 17 and 18. In addition, in the following description, the rotation mechanism 230 located on the third surface 603 of the CDU 100 will be described, but an example of the configuration and an example of the movement of the rotation mechanism 230 located on the fourth surface 604 are similar.

As illustrated in FIG. 17, the third surface 603 of the CDU 100 has a groove portion 190 extending along a direction of insertion and removal of the CDU 100 (X-axis direction). As illustrated in FIG. 18, the rotation mechanism 230 includes a shaft 231, a plurality of bearings 232, and a bushing 233. Note that in the following description, “axial direction” refers to a direction along a rotation axis Ax of the rotation mechanism 230, and a “radial direction” refers to a radial direction of a circle centered on the rotation axis Ax of the rotation mechanism 230.

The shaft 231 extends along the rotation axis Ax. An end portion of the shaft 231 may be located to be movable along the groove portion 190. To be specific, the shaft 231 may include a main body portion 231a extending along the rotation axis Ax and a flange portion 231b protruding in the radial direction from an end portion of the main body portion 231a on a third surface 603 side. The flange portion 231b may be located so as to be in contact with a side surface of the groove portion 190 of the third surface 603 along the direction of insertion and removal (X-axis direction).

The bearings 232 are located in the axial direction of the shaft 231. As illustrated in FIG. 18, the two bearings 232 may be located at both end portions of the main body portion 231a of the shaft 231. The rotation mechanism 230 includes the plurality of bearings 232, so that the rotation mechanism 230 can have a stable structure. Note that while the example with the two bearings 232 is described here, the rotation mechanism 230 may include one bearing 232 or three or more bearings 232. The bushing 233 covers the plurality of bearings 232 from an outer peripheral side.

In the water cooling unit X1 configured as described above, when the CDU 100 is inserted into the rack 200, the end portion of the shaft 231 of the rotation mechanism 230 is guided along the groove portion 190 provided in the CDU 100. At this time, the shaft 231 of the rotation mechanism 230 rotates in accordance with the insertion operation of the CDU 100, that is, the relative movement between the CDU 100 and the rack 200.

This reduces contact resistance between the CDU 100 and the rack 200, enabling the CDU 100 to be smoothly inserted. On the other hand, when the CDU 100 is pulled out from the rack 200, the CDU 100 can be pulled out from the rack 200 by applying force in a direction opposite to the insertion direction. Therefore, by providing the rotation mechanism 230, the water cooling unit X1 can improve ease of insertion and removal of the CDU 100. In addition, presence of the groove portion 190 on the third surface 603 allows the CDU 100 to be inserted and removed along the groove portion 190, making the insertion and removal of the CDU 100 smoother.

As illustrated in FIG. 19, the third surface 603 of the CDU 100 may have a protruding portion 195 that protrudes in the vertical direction (Z-axis direction) from the side surface of the groove portion 190 along the direction of insertion and removal of the CDU 100 (X-axis direction). By having such a protruding portion 195, when the CDU 100 is inserted to a predetermined position in the rack 200, the end portion of the shaft 231 enters by passing over the protruding portion 195 provided in the middle of the groove portion 190 and is positioned behind the protruding portion 195. In this state, the protruding portion 195 restricts movement of the end portion of the shaft 231 in the removal direction (negative X-axis direction), making it difficult for the CDU 100 to be accidentally removed from the rack 200.

On the other hand, when the CDU 100 is to be removed from the rack 200, by applying force in an opposite direction to the insertion direction, the end portion of the shaft 231 moves over the protruding portion 195 along the groove portion 190, enabling the CDU 100 to be removed from the rack 200.

Note that while the example in which the rotation mechanism 230 is located on the side surface 220a of the spacer 220 is described here, the rotation mechanism 230 may be located in the CDU 100. To be specific, the rotation mechanism 230 may be located on the third surface 603 or the fourth surface 604 of the CDU 100 and may be in contact with the side surface 220a of the spacer 220. In this case, the rotation mechanism 230 may rotate in accordance with relative movement of the side surface 220a (rack 200) relative to the third surface 603 or the fourth surface 604 (CDU 100). In this case, the groove portion 190 and the protruding portion 195 may be formed on the side surface 220a.

Note that the present technology can also have configurations such as the following.
(1) A refrigerant circulation device including a housing that accommodates a flow path in which a refrigerant flows, and a pump that is connected to the flow path to pump the refrigerant, a first lever located on a first surface of the housing, the first lever being configured to pivot about a first axis along an in-plane direction of the first surface, a second lever located on the first surface, the second lever being configured to pivot about a second axis along the in-plane direction of the first surface, a first holding portion configured to hold a first end portion, the first end portion being an end portion of two end portions of the first lever and located farther from the first axis in an extension direction of the first lever, a second holding portion configured to hold a second end portion, the second end portion being an end portion of two end portions of the second lever and located farther from the second axis in an extension direction of the second lever, in which a third end portion being another end portion of two end portions of the first lever located closer to the first axis in the extension direction of the first lever, is configured to abut against a first abutment portion of a rack that houses the refrigerant circulation device, a fourth end portion being another end portion of two end portions of the second lever located closer to the second axis in the extension direction of the second lever, is configured to abut against a second abutment portion of the rack, in a state where the first end portion is held by the first holding portion, the third end portion abuts against the first abutment portion, and in a state where the second end portion is held by the second holding portion, the fourth end portion abuts against the second abutment portion.
(2) The refrigerant circulation device according to (1), further including a third lever located on the first surface, in which the first holding portion and the second holding portion are configured to be switched between a restricting state in which the first holding portion and the second holding portion restrict movements of the first lever and the second lever by holding the first end portion and the second end portion, respectively, and a releasing state in which the first holding portion and the second holding portion release the restricting state, and the third lever changes states of the first holding portion and the second holding portion from the restricting state to the releasing state.
(3) The refrigerant circulation device according to (2), in which the first axis and the second axis are parallel or substantially parallel to each other, and the third lever is configured to pivot about a third axis that is along an in-plane direction of the first surface and intersects the first axis and the second axis.
(4) The refrigerant circulation device according to any one of (1) to (3), in which the first lever includes a first protruding portion protruding from the first end portion, the first protruding portion extending in a first direction intersecting the extension direction of the first lever and the first axis, and a first tubular portion connected to the first protruding portion and extending in a direction parallel or substantially parallel to the extension direction of the first lever, the second lever includes a second protruding portion protruding from the second end portion, the second protruding portion extending in a second direction intersecting the extension direction of the second lever and the second axis, and a second tubular portion connected to the second protruding portion and extending in a direction parallel or substantially parallel to the extension direction of the second lever, the first holding portion includes a first hook portion that hooks the first tubular portion, and the second holding portion includes a second hook portion that hooks the second tubular portion.
(5) The refrigerant circulation device according to any one of (2) to (4), in which the third lever is connected to the first holding portion and the second holding portion, and simultaneously switches the states of the first holding portion and the second holding portion.
(6) The refrigerant circulation device according to (4), in which the first lever includes a third protruding portion extending from the first end portion in the first direction, the second lever includes a fourth protruding portion extending from the second end portion in the second direction, the first tubular portion is connected to the first protruding portion at one end portion and connected to the third protruding portion at another end portion, and the second tubular portion is connected to the second protruding portion at one end portion and connected to the fourth protruding portion at another end portion.
(7) The refrigerant circulation device according to any one of (2) to (6), in which the third lever is located closer to a top surface of the housing than the first holding portion and the second holding portion on the first surface, and the third lever at least partially overlaps with the first holding portion and the second holding portion in a vertical direction.
(8) The refrigerant circulation device according to any one of (1) to (7), in which the first lever and the second lever are located at positions overlapping each other in a direction perpendicular or substantially perpendicular to the extension directions of the first lever and the second lever.
(9) A refrigerant circulation device including a housing that accommodates a flow path in which a refrigerant flows, and a pump that is connected to the flow path to pump the refrigerant, a lever located on a first surface of the housing, the lever being configured to pivot about an axis along an in-plane direction of the first surface, a holding portion configured to hold one end portion of both end portions of the lever and located farther from the axis in an extension direction of the lever, a coupling located on a second surface opposite the first surface, in which another end portion of both end portions of the lever located closer to the axis in the extension direction of the lever is configured to be inserted into an abutment portion of a rack that houses the refrigerant circulation device, in a state where the one end portion located farther from the axis is held by the holding portion, the other end portion located closer to the axis is inserted into the abutment portion, the coupling includes a main flow path and an auxiliary flow path that communicate with the flow path, a main valve provided in the main flow path, and an auxiliary valve provided in the auxiliary flow path, and a flow path area of the main flow path is larger than a flow path area of the auxiliary flow path.
(10) The refrigerant circulation device according to (9), in which the coupling includes a first portion including a protruding portion protruding in a direction away from the second surface, and a second portion including a recessed portion that fits into the protruding portion, the first portion includes a first main flow path and a first auxiliary flow path that communicates with the flow path, a first main valve provided in the first main flow path, and a first auxiliary valve provided in the first auxiliary flow path, the second portion includes a second main flow path that communicates with the first main flow path, a second auxiliary flow path that communicates with the first auxiliary flow path, a second main valve provided in the second main flow path, a second auxiliary valve provided in the second auxiliary flow path, and a seal provided along an outer circumferential surface of the second auxiliary valve.
(11) The refrigerant circulation device according to (9) or (10), in which the coupling includes a first portion including a protruding portion protruding in a direction away from the second surface, the first portion includes a first main flow path and a first auxiliary flow path that communicates with the flow path, a first main valve provided in the first main flow path, and a first auxiliary valve provided in the first auxiliary flow path, and the first auxiliary valve protrudes further than the first main valve in a direction away from the second surface.
(12) A water cooling unit including the refrigerant circulation device according to any one of (1) to (11), a rack that houses the refrigerant circulation device, and a rotation mechanism that is located on one of a first side surface of the refrigerant circulation device that opposes the rack and a second side surface of the rack that opposes the refrigerant circulation device, that is in contact with another of the first side surface and the second side surface, and that rotates in accordance with relative movement of the other relative to the one.
(13) The water cooling unit according to (12), in which the rotation mechanism includes a shaft, a plurality of bearings located in an axial direction of the shaft, and a bushing that covers the plurality of bearings from an outer peripheral side.
(14) The water cooling unit according to (13), in which another surface of the housing includes a groove portion extending along a direction of insertion and removal of the refrigerant circulation device, and an end portion of the shaft is movably located along the groove portion.
(15) The water cooling unit according to (14), in which the other surface of the housing includes a protruding portion that protrudes from a side surface of the groove portion along the direction of insertion and removal.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A refrigerant circulation device comprising:
a housing that accommodates a flow path in which a refrigerant flows, and a pump that is connected to the flow path to pump the refrigerant;
a first lever located on a first surface of the housing, the first lever being configured to pivot about a first axis along an in-plane direction of the first surface;
a second lever located on the first surface, the second lever being configured to pivot about a second axis along the in-plane direction of the first surface;
a first holding portion configured to hold a first end portion, the first end portion being an end portion of two end portions of the first lever and located farther from the first axis in an extension direction of the first lever;
a second holding portion configured to hold a second end portion, the second end portion being an end portion of two end portions of the second lever and located farther from the second axis in an extension direction of the second lever; wherein
a third end portion being another end portion of two end portions of the first lever located closer to the first axis in the extension direction of the first lever, is configured to abut against a first abutment portion of a rack that houses the refrigerant circulation device;
a fourth end portion being another end portion of two end portions of the second lever located closer to the second axis in the extension direction of the second lever, is configured to abut against a second abutment portion of the rack;
in a state where the first end portion is held by the first holding portion, the third end portion abuts against the first abutment portion; and
in a state where the second end portion is held by the second holding portion, the fourth end portion abuts against the second abutment portion.

2. The refrigerant circulation device according to claim 1, further comprising:
a third lever located on the first surface; wherein
the first holding portion and the second holding portion are configured to be switchable between a restricting state in which the first holding portion and the second holding portion restrict movements of the first lever and the second lever by holding the first end portion and the second end portion, respectively, and a releasing state in which the first holding portion and the second holding portion release the restricting state; and
the third lever changes states of the first holding portion and the second holding portion from the restricting state to the releasing state.

3. The refrigerant circulation device according to claim 2, wherein
the first axis and the second axis are parallel or substantially parallel to each other; and
the third lever is configured to pivot about a third axis that is along an in-plane direction of the first surface and intersects the first axis and the second axis.

4. The refrigerant circulation device according to claim 1, wherein
the first lever includes:
a first protruding portion protruding from the first end portion, the first protruding portion extending in a first direction intersecting the extension direction of the first lever and the first axis; and
a first tubular portion connected to the first protruding portion and extending in a direction parallel or substantially parallel to the extension direction of the first lever;
the second lever includes:
a second protruding portion protruding from the second end portion, the second protruding portion extending in a second direction intersecting the extension direction of the second lever and the second axis; and
a second tubular portion connected to the second protruding portion and extending in a direction parallel or substantially parallel to the extension direction of the second lever;
the first holding portion includes a first hook portion that hooks the first tubular portion; and
the second holding portion includes a second hook portion that hooks the second tubular portion.

5. The refrigerant circulation device according to claim 2, wherein
the third lever is connected to the first holding portion and the second holding portion, and simultaneously switches the states of the first holding portion and the second holding portion.

6. The refrigerant circulation device according to claim 4, wherein
the first lever includes a third protruding portion extending from the first end portion in the first direction;
the second lever includes a fourth protruding portion extending from the second end portion in the second direction;
the first tubular portion is connected to the first protruding portion at one end portion and connected to the third protruding portion at another end portion; and
the second tubular portion is connected to the second protruding portion at one end portion and connected to the fourth protruding portion at another end portion.

7. The refrigerant circulation device according to claim 2, wherein
the third lever is located closer to a top surface of the housing than the first holding portion and the second holding portion on the first surface; and
the third lever at least partially overlaps with the first holding portion and the second holding portion in a vertical direction.

8. The refrigerant circulation device according to claim 1, wherein
the first lever and the second lever are located at positions overlapping each other in a direction perpendicular or substantially perpendicular to the extension directions of the first lever and the second lever.

9. A refrigerant circulation device comprising:
a housing that accommodates a flow path in which a refrigerant flows, and a pump that is connected to the flow path to pump the refrigerant;
a lever located on a first surface of the housing, the lever being configured to pivot about an axis along an in-plane direction of the first surface;
a holding portion configured to hold one end portion of two end portions of the lever and located farther from the axis in an extension direction of the lever;
a coupling located on a second surface opposite the first surface; wherein
another end portion of two end portions of the lever located closer to the axis in the extension direction of the lever is configured to be inserted into an abutment portion of a rack that houses the refrigerant circulation device;
in a state where the one end portion located farther from the axis is held by the holding portion, another end portion located closer to the axis is inserted into the abutment portion;
the coupling includes:
a main flow path and an auxiliary flow path that communicates with the flow path;
a main valve provided in the main flow path; and
an auxiliary valve provided in the auxiliary flow path; and
a flow path area of the main flow path is larger than a flow path area of the auxiliary flow path.

10. The refrigerant circulation device according to claim 9, wherein
the coupling includes:
a first portion including a protruding portion protruding in a direction away from the second surface; and
a second portion including a recessed portion that fits into the protruding portion,
the first portion includes:
a first main flow path and a first auxiliary flow path that communicate with the flow path;
a first main valve provided in the first main flow path; and
a first auxiliary valve provided in the first auxiliary flow path; and
the second portion includes:
a second main flow path that communicates with the first main flow path;
a second auxiliary flow path that communicates with the first auxiliary flow path;
a second main valve provided in the second main flow path;
a second auxiliary valve provided in the second auxiliary flow path; and
a seal provided along an outer circumferential surface of the second auxiliary valve.

11. The refrigerant circulation device according to claim 9, wherein
the coupling includes:
a first portion including a protruding portion protruding in a direction away from the second surface;
the first portion includes:
a first main flow path and a first auxiliary flow path that communicate with the flow path;
a first main valve provided in the first main flow path; and
a first auxiliary valve provided in the first auxiliary flow path; and
the first auxiliary valve protrudes further than the first main valve in a direction away from the second surface.

12. A water cooling unit comprising:
the refrigerant circulation device according to claim 1;
a rack that houses the refrigerant circulation device; and
a rotation mechanism that is located on one of a first side surface of the refrigerant circulation device that opposes the rack and a second side surface of the rack that opposes the refrigerant circulation device, that is in contact with another of the first side surface and the second side surface, and that rotates in accordance with relative movement of the other relative to the one.

13. The water cooling unit according to claim 12, wherein
the rotation mechanism includes:
a shaft;
a plurality of bearings located in an axial direction of the shaft; and
a bushing that covers the plurality of bearings from an outer peripheral side.

14. The water cooling unit according to claim 13, wherein
another surface of the housing includes a groove portion extending along a direction of insertion and removal of the refrigerant circulation device; and
an end portion of the shaft is movably located along the groove portion.

15. The water cooling unit according to claim 14, wherein
the another surface of the housing includes a protruding portion that protrudes from a side surface of the groove portion along the direction of insertion and removal.
